(19) United States
(12) Patent Application Publication
(10) Pub. No.: US 2024/0260394 A1
(43) Pub. Date: Aug. 1, 2024

(54) DISPLAY APPARATUS

(71) Applicant: LG Display Co., Ltd., Seoul (KR)

(72) Inventor: Jeong Hoon LEE, Paju-si (KR)

(73) Assignee: LG Display Co., Ltd., Seoul (KR)

(21) Appl. No.: 18/412,093

(22) Filed: Jan. 12, 2024

(30) Foreign Application Priority Data
Jan. 30, 2023 (KR) 10-2023-0011913

(51) Int. Cl. H10K 59/80

(52) U.S. Cl. CPC H10K 59/872; H10K 2102/311

(57) ABSTRACT

A display apparatus in one example includes a display panel having a curvature, a cover member attached to a display surface of the display panel, and a support member attached to a rear surface of the display panel. Further, the support member is flexible in a curvature direction of the display panel.

### CROSS-REFERENCE TO RELATED APPLICATIONS

This application claims priority to Korean Patent Application No. 10-2023-0011913, filed in the Republic of Korea on Jan. 30, 2023, the entire contents of which are hereby expressly incorporated by reference into the present application.

### BACKGROUND

### Field

The present disclosure relates to a display apparatus with an improved support structure.

### Discussion of the Related Art

With a recent approach to a full-scale information age, displays capable of visually expressing electrical information signals have been rapidly developed. As such, various display apparatuses having excellent performance and configurations, such as slimness, light weight, and low power consumption, have been developed and used.

There are a liquid crystal display (LCD) apparatus, an organic light-emitting display (OLED) apparatus, and an inorganic light-emitting display apparatus as examples of the display apparatuses. The organic light-emitting display (OLED) apparatus, which is considered as a next-generation display apparatus having self-emissive properties, exhibits excellent characteristics in terms of viewing angle, contrast, response time, power consumption, etc.

Since a light-emitting element can be disposed on a flexible substrate, the organic light-emitting display (OLED) apparatus is in the spotlight to be used as a flexible display apparatus, such as a bendable display apparatus, a foldable display apparatus, or a rollable display apparatus.

### SUMMARY OF THE DISCLOSURE

Accordingly, the present disclosure is directed to a display apparatus that substantially obviates one or more problems due to limitations and disadvantages of the related art.

It is an object of the present disclosure to provide a display apparatus having concave portions and convex portions formed in a curvature direction of the display apparatus, thereby preventing stress when the display apparatus is coupled to a set or another structure.

It is another object of the present disclosure to provide a display apparatus capable of dispersing force applied from a rear attachment structure for set fastening, thereby preventing front stains.

Objects of the present disclosure devised to solve or address the problems and issues are not limited to the aforementioned objects and limitations, and other unmentioned objects and limitations will be clearly understood by those skilled in the art based on the following detailed description of the present disclosure.

To achieve the above object and other advantages and in accordance with the purpose of the invention, as embodied and broadly described herein, a display apparatus includes a display panel having a curvature, a cover member attached to a display surface of the display panel, and a support member attached to a rear surface of the display panel, where the support member is flexible in a curvature direction of the display panel.

It is to be understood that both the foregoing general description and the following detailed description of the present disclosure are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1 is a block diagram schematically showing the construction of a display apparatus according to an embodiment of the present disclosure;

FIG. 2 is a rear view of the display apparatus according to the embodiment of the present disclosure;

FIG. 3 is a sectional view of the display apparatus according to the embodiment of the present disclosure in a curvature direction;

FIG. 4 is a sectional view of the display apparatus, taken along line I-I′ of FIG. 2;

FIG. 5 is a view showing the construction of a support member of a display apparatus according to another embodiment of the present disclosure;

FIG. 6 is a view showing the construction of a support member of a display apparatus according to another embodiment of the present disclosure;

FIG. 7 is a view showing the construction of a support member of a display apparatus according to another embodiment of the present disclosure;

FIG. 8 is a sectional view of a support member of a display apparatus according to another embodiment of the present disclosure; and

FIG. 9 is a sectional view of a support member of a display apparatus according to a further embodiment of the present disclosure.

### DETAILED DESCRIPTION OF THE EMBODIMENTS

Advantages and features of the present disclosure and methods of achieving the same will be more clearly understood from embodiments described below with reference to the accompanying drawings. However, the present disclosure is not limited to the following embodiments and can be implemented in various different forms. The embodiments are provided merely to complete the present disclosure and to fully inform a person having ordinary skill in the art to which the present disclosure pertains of the category of the invention. The present disclosure is defined only by the category of the claims.

In the drawings for explaining various embodiments of the present disclosure, for example, the illustrated shape, size, ratio, angle, and number are given by way of example, and thus, are not limitative of the present disclosure. Throughout the specification, the same reference numerals designate substantially the same constituent elements. Further, in the following description of the present disclosure, a detailed description of relevant known technology will be omitted when it can make the subject matter of the present disclosure rather unclear. The phrase ‘present disclosure’ encompasses the full meaning of ‘present invention’.

When the terms “comprises”, “includes”” “has”, etc. are used in this specification, other parts can be added unless the term “only” is used. When constituent elements are expressed in singular, they can be interpreted as plural unless explicitly stated otherwise.

In the interpretation of constituent elements, the constituent elements are interpreted as including an error range even if there is no explicit description thereof.

When describing positional relationships, for example, when the positional relationship between two constituent elements is described using “on”, “above”, “below”, “aside”, or the like, one or more other constituent elements can be interposed between the constituent elements unless the term “immediately” or “directly” is used therewith.

Further, “first”, “second”, etc. can be used to distinguish between constituent elements, but the constituent elements are not limited in function or structure by the ordinal numbers in front thereof or the names thereof. Since the claims are described based on essential constituent elements, the ordinal numbers in front of the names of the constituent elements in the claims may not match the ordinal numbers in front of the names of the constituent elements in the embodiments.

The following embodiments can be partially or wholly coupled to and combined with each other, and various linkages and operations are technically possible. The embodiments can be implemented independently of each other, or can be implemented in association with each other.

Hereinafter, a display apparatus according to one or more embodiments and aspects of the present disclosure will be described in more detail with reference to the accompanying drawings. All the components of each display apparatus or device according to all embodiments of the present disclosure are operatively coupled and configured.

FIG. 1 is a block diagram schematically showing the construction of a display apparatus according to an embodiment of the present disclosure.

Referring to FIG. 1, the display apparatus according to the embodiment of the present disclosure includes a display panel 100 having pixels PXL formed thereon, a data drive circuit 120 configured to drive data lines 140, a gate drive circuit 130 configured to drive gate lines 150, and a timing controller 110 configured to control driving timing of the data drive circuit 120 and the gate drive circuit 130. The display panel 100 can include the gate drive circuit 130. Embodiments of the present disclosure are not limited thereto.

The plurality of data lines 140 and the plurality of gate lines 150 intersect each other on the display panel 100, and the pixels PXL are disposed at intersection regions in a matrix form. However, the pixels PXL can be arranged in different configurations. In an example, pixels PXL disposed on the same horizontal line form one pixel row. Pixels PXL disposed in one pixel row are connected to one gate line 150, which can include at least one scan line and at least one emission line. For example, each pixel PXL can be connected to one data line 140, at least one scan line, and at least one emission line. The pixels PXL can commonly receive high-potential and low-potential drive voltages ELVDD and ELVSS and an initialization voltage Vinit from a power generator. In order to prevent unnecessary emission of an OLED during an initialization period and a sampling period, the initialization voltage Vinit is preferably selected within a voltage range sufficiently lower than the operating voltage of the OLED, and can be set so as to be equal to or lower than the low-potential drive voltage ELVSS.

Each of thin film transistors (TFTs) constituting each of the pixels PXL can be implemented as an oxide TFT including, for example, an oxide semiconductor layer. The oxide TFT is advantageous to an increase in area of the display panel 100 when electron mobility, process variation, etc. are considered. The present disclosure is not limited thereto, and the semiconductor layer of the TFT can be made of amorphous silicon or polysilicon.

Each pixel PXL can include a light-emitting element, a drive TFT configured to supply current to the light-emitting element, a switching TFT configured to supply a data voltage to the drive TFT, and a storage capacitor configured to maintain the data voltage supplied to the drive TFT for one frame. Each pixel PXL can further include a plurality of TFTs and an additional storage capacitor in order to compensate for change in threshold voltage of the drive TFT.

The timing controller 110 rearranges the digital video data RGB input from the outside so as to match the resolution of the display panel 100 and supplies the rearranged data RGB to the data drive circuit 120. In addition, the timing controller 110 generates a data control signal DDC for controlling operation timing of the data drive circuit 120 and a gate control signal GDC for controlling operation timing of the gate drive circuit 130 based on timing signals such as a vertical synchronization signal Vsync, a horizontal synchronization signal Hsync, a dot clock signal DCLK, and a data enable signal DE.

The data drive circuit 120 converts the digital video data RGB input from the timing controller 110 into analog data voltage based on the data control signal DDC, and provides the same to each data line 140.

The data drive circuit 120 can include at least one source drive integrated circuit (IC) SIC. Under the control of the timing controller 110, the source drive IC SIC converts the digital video data of the input video to an analog gamma compensation voltage to generate a data voltage and outputs the data voltage to the data lines 140. The source drive IC SIC can be mounted on a bendable flexible circuit board, such as a chip on film COF, or can be directly bonded to a substrate in a non-display area of the display panel 100 through a chip on glass COG process.

The COFs are bonded to a pad area of the display panel 100 and a source PCB via an anisotropic conductive film ACF. Input pins of the COFs are electrically connected to output terminals (pads) of the source PCB. Output pins of the source COFs are electrically connected to data pads formed on the substrate of the display panel 100 via the ACF.

The gate drive circuit 130 can generate a scan signal and an emission signal based on the gate control signal GDC. The gate drive circuit 130 can include a scan driver and an emission driver. The scan driver can generate a scan signal in a row-sequential manner and can supply the scan signal to the gate lines 150 in order to drive at least one scan line connected to each pixel row. The emission driver can generate an emission signal in a row-sequential manner and can supply the emission signal to the emission lines in order to drive at least one emission line connected to each pixel row.

For example, the gate drive circuit 130 can be formed in the non-display area of the display panel 100 in a gate-driver in panel (GIP) fashion. The gate drive circuit 130 can be formed in a display area. The gate drive circuit 130 can be formed outside the panel. Embodiments of the present disclosure are not limited thereto.

The display panel 100 can use a plastic material (PI: polyimide) as a substrate. The plurality of data lines 140 and the plurality of gate lines 150 can be disposed on the plastic substrate. A light-emitting element, a drive TFT configured to supply current to the light-emitting element, a switching TFT configured to supply a data voltage to the drive TFT, and a storage capacitor configured to maintain the data voltage supplied to the drive TFT for one frame can be disposed in each pixel PXL.

Therefore, the display panel 100 according to the embodiment of the present disclosure can have a curved surface (curvature), and can be formed as a display apparatus other than a quadrangular display apparatus. Furthermore, the display apparatus according to the embodiment of the present disclosure can be utilized as a dashboard in a vehicle or the like.

If a curved flexible display apparatus is used as a dashboard in a vehicle, however, it may not be possible for the display apparatus to have the same curvature as a set in the vehicle due to the structural characteristics thereof, Therefore, the probability of stress occurrence can be high when the display apparatus is coupled to the set.

Further, if a part that receives local force is attached to the rear surface of the display apparatus, stains can be visible on a front surface of the display apparatus, which is not desirable and is a limitation to be addressed.

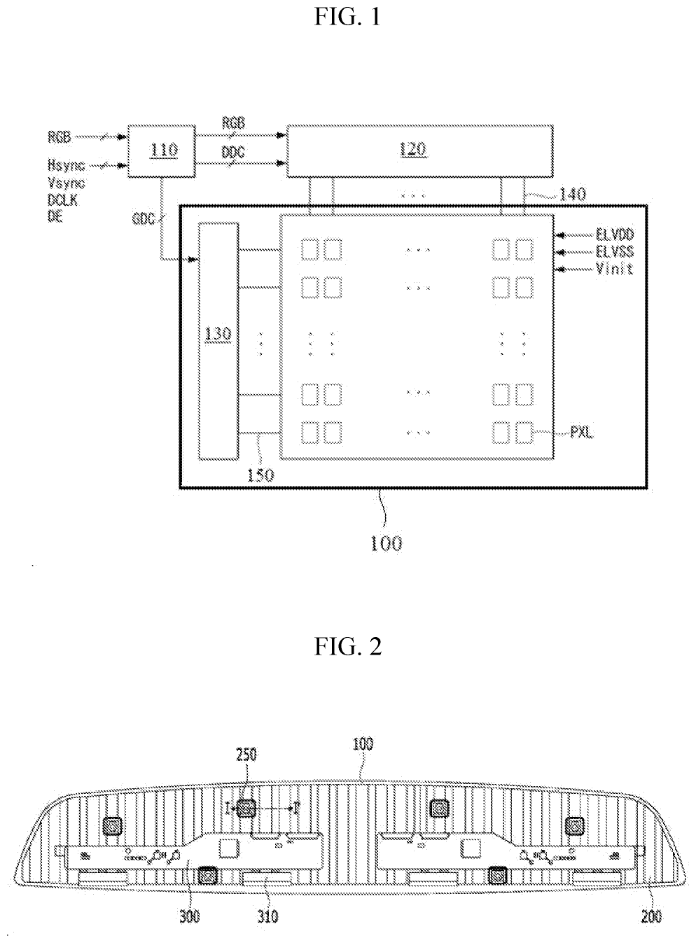

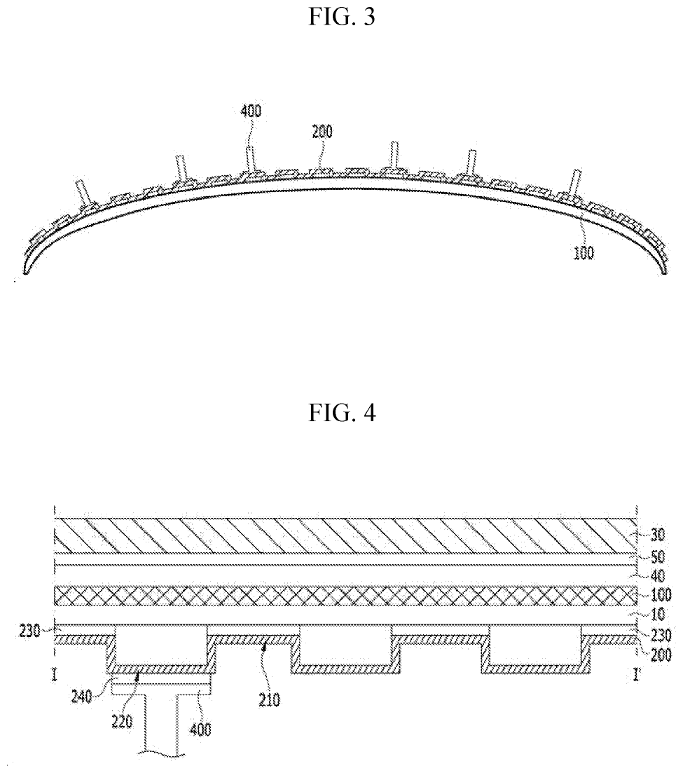

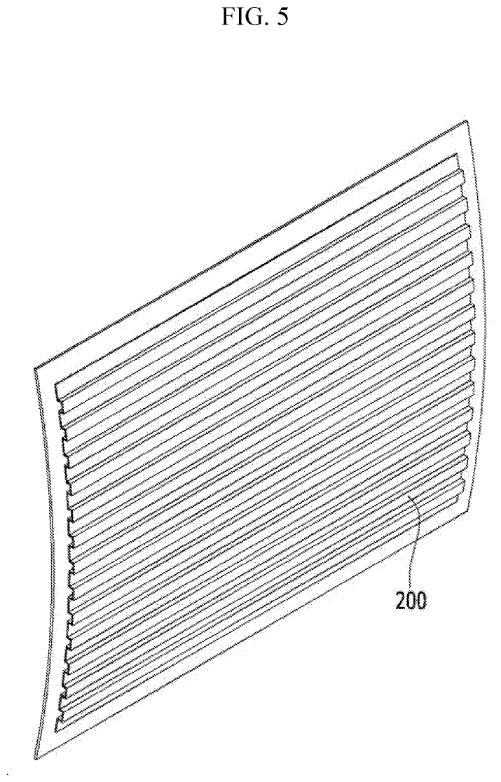

Accordingly, the present disclosure provides an improved display apparatus that addresses these issues. For example, FIG. 2 is a rear view of the display apparatus according to the embodiment of the present disclosure, and FIG. 3 is a sectional view of the display apparatus according to the embodiment of the present disclosure in a curvature direction. FIG. 4 is a sectional view of the display apparatus, taken along line I-I′ of FIG. 2.

In the display apparatus according to the embodiment of the present disclosure, as shown in FIGS. 2 and 3, a support member 200 that is flexible in a curvature direction of the display panel 100 (along a line thereof) can be attached to the rear surface of the display panel 100 having the curvature.

The support member 200 can have concave portions and convex portions so as to be flexible in the curvature direction of the display panel 100 (along the line thereof). An extension direction of the concave portions and the convex portions of the support member 200 can be perpendicular to the curvature direction of the display panel 100.

A bolting structure (or the like) for set attachment can be attached to at least one of the convex portions of the support member 200. In FIG. 2, a position 250 at which the bolting structure is attached is shown as an example, and multiple bolting structures can be provided.

A source printed circuit board (PCB) 300 can be disposed on a rear surface of the support member 200. The source PCB 300 can be bonded to a pad area of the display panel 100 via a flexible printed circuit film 310. A data drive circuit 120 or a timing controller 110, described with reference to FIG. 1, can be disposed on the source PCB 300.

FIGS. 2 and 3 show that, in accordance with the embodiment of the present disclosure, when the curvature direction of the display panel 100 is a horizontal direction, the extension direction of the concave portions and the convex portions of the support member 200 is a vertical direction. For example, the concave and convex portions of the support member 200 can extend vertically as shown in FIG. 2 while the display panel 100 can curve and extend curved horizontally as shown in FIG. 3. However, the present disclosure is not limited thereto. The structure shown in FIG. 4 will be discussed below later.

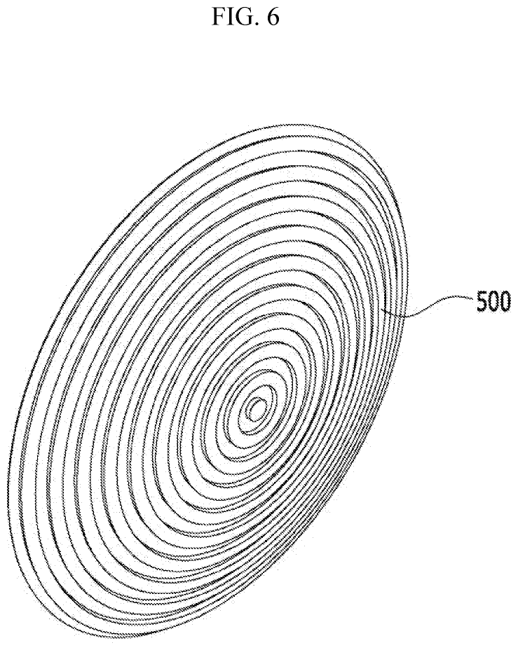

FIG. 5 is a view showing the construction of a support member 200 of a display apparatus according to another embodiment of the present disclosure.

Referring to FIG. 5, when the curvature direction of the display panel 100 is a vertical direction (e.g., the display panel 100 extends curved vertically), the extension direction of the concave portions and the convex portions of the support member 200 can be a horizontal direction (e.g., the concave and convex portions extend horizontally).

FIG. 6 is a view showing the construction of a support member 500 of a display apparatus according to another embodiment of the present disclosure. The support member 500 can be coupled with the display panel 100 or the like, similar to the support member 200.

Referring to FIG. 6, when the display panel 100 has a convex curvature shape, the extension direction of the concave portions and the convex portions of the support member 500 can be circular. For example, the concave and convex portions of the support member 500 form concentric circles or concentric circular shapes.

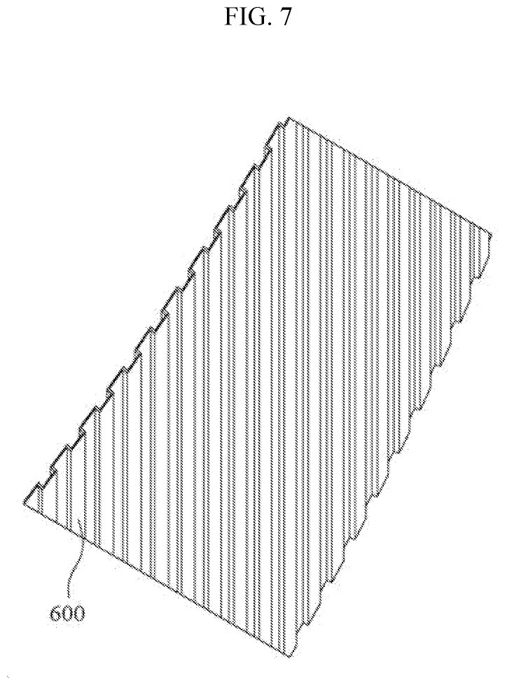

FIG. 7 is a view showing the construction of a support member 600 of a display apparatus according to another embodiment of the present disclosure.

Referring to FIG. 7, when the display panel 100 has a diagonal curvature shape, the extension direction of the concave portions and the convex portions of the support member 600 can be a diagonal direction perpendicular to the curvature direction of the display panel 100. For example, the concave and convex portions of the support member 600 can extend diagonally, which can be perpendicular to the direction in which the display panel 100 extends. The support member 600 can be coupled with the display panel 100 or the like, similar to the support member 200.

Now returning to FIG. 4 depicting a sectional view of the display apparatus, taken along line I-I′ of FIG. 2, in the display apparatus according to the embodiment of the present disclosure, a cover member 30 is located on a display surface of the display panel 100, and a plate 10 can be adhered to the rear surface of the display panel 100 via an adhesive member.

An optical film 40 can be further provided between the display panel 100 and the cover member 30. The optical film 40 can include a diffusion sheet, a prismatic sheet, and a polarizer.

The optical film 40 and the cover member 30 can be adhered to each other via an optically clear adhesive (OCA) 50.

The cover member 30 can include a cover glass and a cover window. A black layer can be further included in a bezel area of the cover member 30.

The display panel 100 can include a plurality of light-emitting display elements. The display panel 100 can include a flexible substrate and a plurality of light-emitting display elements formed on the flexible substrate. The flexible substrate can include a polyimide substrate.

The plate 10 can have functions to dissipate heat of the display panel 100 and to support the rear surface of the display panel 100. The plate 10 can be made of a material having a heat dissipation effect, such as copper (Cu) or aluminum (Al).

The support member 200 according to the embodiment of the present disclosure, described with reference to FIG. 2, can be attached to a rear surface of the plate 10 via a first adhesive 230.

As described in FIGS. 2 to 4, the support member 200 has the concave portions 210 and the convex portions 220. The first adhesive 230 is located between the concave portions 210 of the support member 200 and the rear surface of the plate 10, and the concave portions 210 of the support member 200 are attached to the rear surface of the plate 10 via the first adhesive 230.

In addition, the bolting structure 400 for set attachment can be attached to at least one of the convex portions 220 of the support member 200. At least one of the convex portions 220 of the support member 200 and the bolting structure 400 can be adhered to each other via a second adhesive 240.

FIG. 4 shows that the support member 200 has the concave portions 210 and the convex portions 220 when viewed in section and that the sectional shape of the convex portion 220 is rectangular. The concave portions and the convex portions of the support member 200 can be alternately formed in a “[” shape. The shape of the support member 200 is not limited thereto. An opening can be provided between the support member 200 and the plate 10. An opening can be provided between the convex portions 220 of the support member 200 and the plate 10.

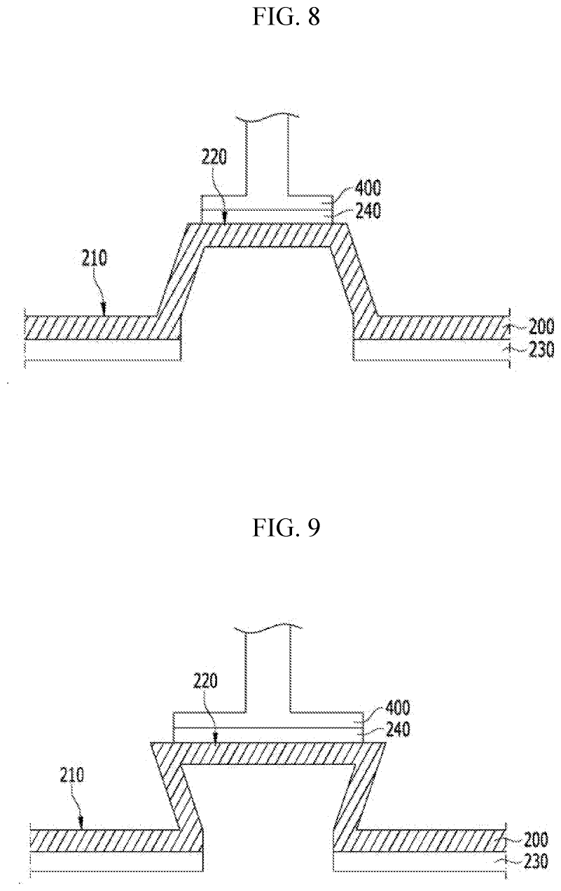

FIG. 8 is a sectional view of a support member 200 of a display apparatus according to another embodiment of the present disclosure.

As shown in FIG. 8, the sectional shape of each of at least one convex portion of the support member 200 can be trapezoidal. In this case, it is possible to improve stiffness and stress distribution, for example, when an attachment structure, such as a bolting structure 400, is narrow.

FIG. 9 is a sectional view of a support member 200 of a display apparatus according to a further embodiment of the present disclosure.

As shown in FIG. 9, the sectional shape of each of at least one convex portion of the support member 200 can be inverted trapezoidal. In this case, it is possible to improve stiffness and stress distribution, for example, when an attachment structure, such as a bolting structure 400, is wide.

For example, the support member 200 is not attached to the rear surface of the display apparatus, and the set is coupled to the rear surface of the plate constituting the display apparatus. Consequently, if the shape of a display apparatus having a curved surface and the shape of the set do not match when the display apparatus having the curved surface and the set are coupled to each other using a bolt or an adhesive, stress can be applied to the display apparatus having the curved surface, whereby the display apparatus can be defective.

In the display apparatus according to the embodiment of the present disclosure, the support member 200 having the concave portions 210 and the convex portions 220 in the curvature direction of the display apparatus is attached to the rear surface of the display apparatus, and the set is coupled to the convex portions 220 of the support member 200. Even though the display apparatus does not have the same curvature as the set in the vehicle, therefore, it is possible to reduce the occurrence of stress of the display apparatus when being coupled to the set.

For example, when the set is coupled to the rear surface of the thin plate constituting the display apparatus, local force (compression or tension) is applied to the display apparatus by the bolting structure, whereby stains corresponding thereto can occur on the front surface of the display apparatus.

In the display apparatus according to the embodiment of the present disclosure, the support member 200 having the concave portions 210 and the convex portions 220 in the curvature direction of the display apparatus is attached to the rear surface of the display apparatus, and the set is coupled to the convex portions 220 of the support member 200. Consequently, it is possible to disperse compressive or tensile pressure applied to the display apparatus, thereby preventing the occurrence of stains.

A display apparatus according to an embodiment of the present disclosure can include a display panel having curvature, a cover member attached to a display surface of the display panel, and a support member attached to a rear surface of the display panel, the support member being flexible in a curvature direction of the display panel.

The support member can have a concave portion and a convex portion, and an extension direction of the concave portion and the convex portion can be perpendicular to the curvature direction of the display panel.

When the curvature direction of the display panel is a horizontal direction, the extension direction of the concave portion and the convex portion of the support member can be a vertical direction.

When the curvature direction of the display panel is a vertical direction, the extension direction of the concave portion and the convex portion of the support member can be a horizontal direction.

When the display panel has a convex curvature shape, the extension direction of the concave portion and the convex portion of the support member can be circular.

When the display panel has a diagonal curvature shape, the extension direction of the concave portion and the convex portion of the support member can be a diagonal direction perpendicular to the curvature direction of the display panel.

The sectional shape of the convex portion of the support member can be rectangular.

The sectional shape of the convex portion of the support member can be trapezoidal.

The sectional shape of the convex portion of the support member can be inverted trapezoidal.

An optical film can be further provided between the display panel and the cover member.

A plate can be further provided between the display panel and the support member.

The support member can have a plurality of concave portions and a plurality of convex portions, the plurality of concave portions can be attached to the plate via a first adhesive, and a bolting structure of a set can be attached to at least one of the plurality of convex portions via a second adhesive.

As is apparent from the above description, a display apparatus according to the present disclosure having the above-described features has the following effects.

In a display apparatus according to an embodiment of the present disclosure, a support member having concave portions and convex portions in a curvature direction of the display apparatus is attached to a rear surface of the display apparatus, and a set is coupled to the convex portions of the support member. Even though the display apparatus does not have the same curvature as the set in the vehicle, therefore, it is possible to reduce the occurrence of stress of the display apparatus when being coupled to the set.

Further, in the display apparatus according to the embodiment of the present disclosure, the support member having the concave portions and the convex portions in the curvature direction of the display apparatus is attached to the rear surface of the display apparatus, and the set is coupled to the convex portions of the support member 200. Consequently, it is possible to disperse compressive or tensile pressure applied to the display apparatus, thereby preventing the occurrence of stains.

Even though the display apparatus does not have the same curvature as the set, it is possible to mount the display apparatus to the set while no stress is applied to the display apparatus, whereby the process can be optimized and energy for production can be reduced.

Effects of the present disclosure are not limited by the above mentioned effects, and other unmentioned effects can be clearly understood from the above description by those skilled in the art.

The description of problems to be solved, means to solve the problems, and effects of the present disclosure do not specify essential features of the claims, and the scope of the claims is not limited by the detailed description of the invention.

Those skilled in the art will understand that various modification and alternations are possible from the above description without departing from the technical idea of the present disclosure. Consequently, the technical scope of the present disclosure is defined by the appended claims, not by the detailed description of the present disclosure.

What is claimed is:

1. A display apparatus comprising:
a display panel having a curvature;
a cover member attached to a display surface of the display panel; and
a support member attached to a rear surface of the display panel, the support member being flexible in a curvature direction of the display panel.

2. The display apparatus according to claim 1, wherein the support member has at least one concave portion and at least one convex portion.

3. The display apparatus according to claim 2, wherein an extension direction of the at least one concave portion and the at least one convex portion of the support member is substantially perpendicular to the curvature direction of the display panel.

4. The display apparatus according to claim 2, wherein, when the curvature direction of the display panel is a horizontal direction, an extension direction of the at least one concave portion and the at least one convex portion of the support member is a vertical direction.

5. The display apparatus according to claim 2, wherein, when the curvature direction of the display panel is a vertical direction, an extension direction of the at least one concave portion and the at least one convex portion of the support member is a horizontal direction.

6. The display apparatus according to claim 2, wherein, when the display panel has a convex curvature shape, an extension direction of the at least one concave portion and the at least one convex portion of the support member is circular.

7. The display apparatus according to claim 2, wherein, when the display panel has a diagonal curvature shape, an extension direction of the at least one concave portion and the at least one convex portion of the support member is a diagonal direction that is perpendicular to the curvature direction of the display panel.

8. The display apparatus according to claim 2, wherein a sectional shape of each of the at least one convex portion of the support member is rectangular.

9. The display apparatus according to claim 2, wherein a sectional shape of each of the at least one convex portion of the support member is trapezoidal.

10. The display apparatus according to claim 2, wherein a sectional shape of each of the at least one convex portion of the support member is inverted trapezoidal.

11. The display apparatus according to claim 1, further comprising an optical film provided between the display panel and the cover member.

12. The display apparatus according to claim 1, further comprising a plate provided between the display panel and the support member.

13. The display apparatus according to claim 12, wherein
the support member has a plurality of concave portions and a plurality of convex portions,
the plurality of concave portions are attached to the plate via a first adhesive, and
a bolting structure of a set is attached to at least one of the plurality of convex portions via a second adhesive.

14. The display apparatus according to claim 13, wherein an opening is provided between the plurality of convex portions of the support member and the plate.

15. The display apparatus according to claim 1, wherein the display apparatus is part of a dashboard in a vehicle.
